(19) United States
(12) Patent Application Publication
(10) Pub. No.: US 2008/0296674 A1
(43) Pub. Date: Dec. 4, 2008

(54) TRANSISTOR, INTEGRATED CIRCUIT AND METHOD OF FORMING AN INTEGRATED CIRCUIT

(75) Inventors: Andrew Graham, Dresden (DE); Jessica Hartwich, Dresden (DE); Arnd Scholz, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/755,141

(22) Filed: May 30, 2007

(51) Int. Cl. H01L 29/78; H01L 21/336

(52) U.S. Cl. 257/334; 257/330; 438/272; 257/E21.41; 257/E29.262

(57) ABSTRACT

A transistor, an integrated circuit and a method of forming an integrated circuit is disclosed. One embodiment includes a gate electrode. The gate electrode is disposed in a gate groove formed in a semiconductor substrate and includes a conductive carbon material.

### BACKGROUND

The present specification relates to a transistor, an integrated circuit as well as to an electronic device. The specification further refers to a method of forming an integrated circuit.

Memory cells of a dynamic random access memory (DRAM) generally include a storage capacitor for storing an electrical charge which represents an information to be stored, and an access transistor which is connected with the storage capacitor. A memory cell array further includes wordlines which are coupled to the gate electrodes of corresponding transistors as well as bitlines which are coupled to corresponding doped portions of the transistors. A transistor type which may be employed is the RCAT (“Recessed Channel Array Transistor”) in which the gate electrode is formed in a gate groove that is defined in the substrate surface. Memory devices having RCATs may, for example, include buried wordlines. By way of example, the wordlines may be completely buried so that a surface of the wordlines is disposed beneath a semiconductor substrate surface. Generally, the resistivity of the wordline determines the switching speed of a memory device.

Generally, a DRAM memory cell array which has a high degree of reliability in its operation characteristic is desired.

For these and other reasons, there is a need for the present invention.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a cross-sectional view of a transistor according to an embodiment;

FIG. 2 illustrates a cross-sectional view of a transistor according to another embodiment;

FIG. 3A illustrates a cross-sectional view of a transistor according to still another embodiment;

FIG. 3B illustrates a cross-sectional view of a transistor according to a further embodiment;

FIG. 3C illustrates a cross-sectional view of a transistor according to still a further embodiment;

FIGS. 4A to 4C illustrate cross-sectional views of a transistor according to still another embodiment;

FIGS. 5A and 5B illustrate cross-sectional views of transistors according to further embodiments;

FIG. 6A illustrates a schematic plan view of an exemplary memory device;

FIG. 6B illustrates a cross-sectional view of an integrated circuit according to another embodiment of the invention;

FIG. 6C illustrates a plan view of an integrated circuit;

FIGS. 6D and 6E illustrate cross-sectional views of integrated circuits according to embodiments of the invention;

FIGS. 7A and 7B illustrate exemplary plan views of a substrate or integrated circuit, respectively;

FIG. 8 illustrates a flowchart illustrating a method according to an embodiment;

FIGS. 9A to 9C illustrate cross-sectional views of a substrate when performing a method according to an embodiment;

FIGS. 10A to 10D illustrate cross-sectional views of a substrate when performing a method according to an embodiment; and

FIG. 11 illustrates a schematic view of an electronic device.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

As will be explained in the following, a transistor may include a gate electrode, wherein the gate electrode is disposed in a gate groove formed in a semiconductor substrate, the gate electrode having a conductive carbon material. Moreover, an integrated circuit may include transistors, the transistors having a gate electrode, wherein the gate electrode is disposed in a gate groove formed in a semiconductor substrate, the gate electrode having a conductive carbon material.

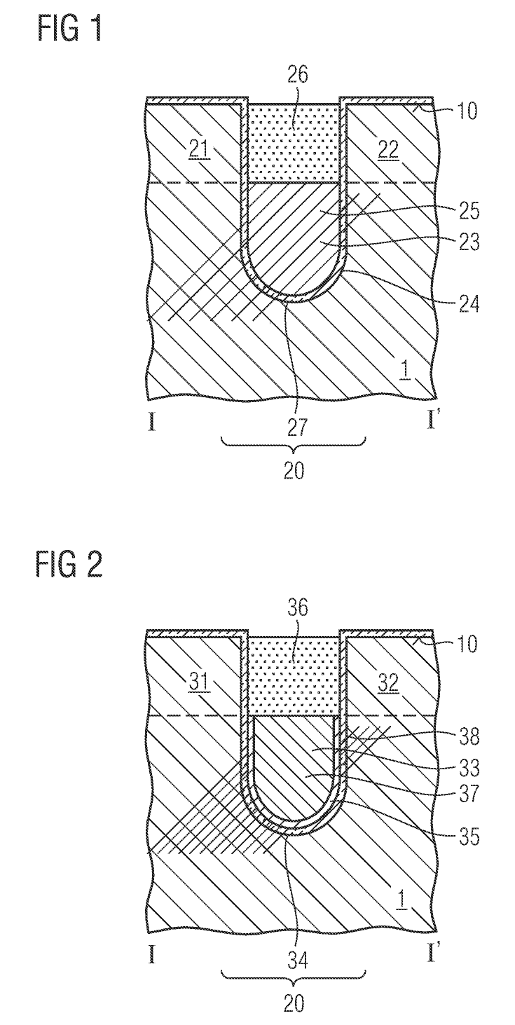

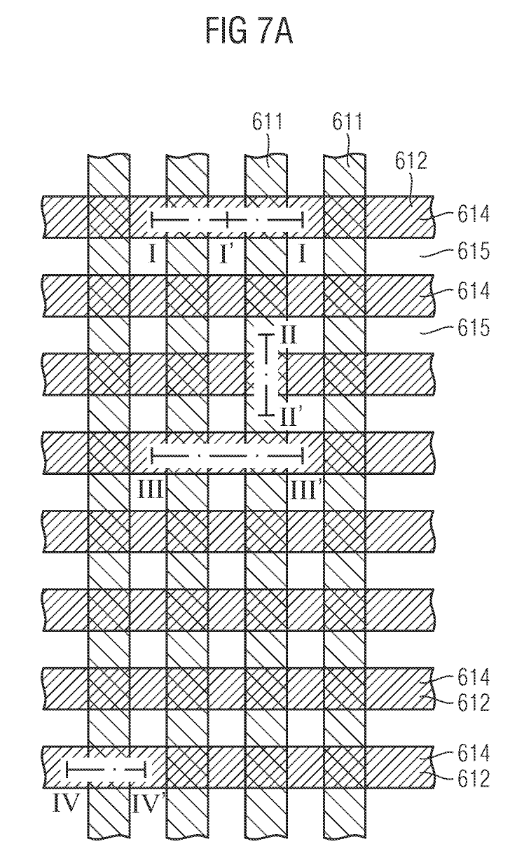

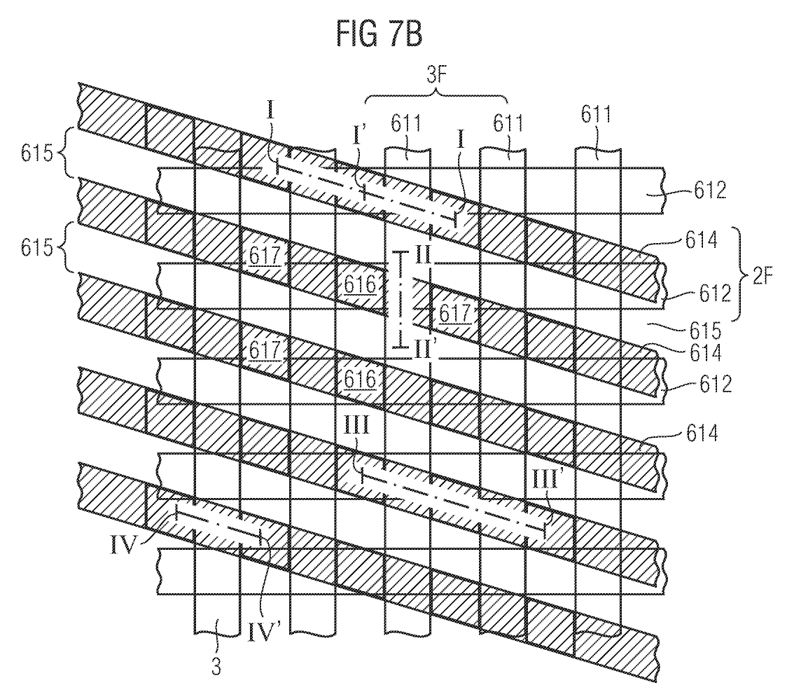

FIG. 1 illustrates a cross-sectional view of a transistor according to an embodiment. The direction of the cross-sectional view of FIG. 1 can, for example, be taken from FIGS. 7A and 7B. A first and a second doped portion forming the first and the second source/drain portion 21, 22 are defined adjacent to a main surface 10 of a semiconductor substrate 1. The terms “wafer”, “substrate” or “semiconductor substrate” used in the context of the present description may include any semiconductor-based structure that has a semiconductor substrate. Wafer and substrate are to be understood to include silicon, silicon-on-insulator (SOI), silicon-on-sapphire (SOS), doped and undoped semiconductors, epitaxial layers of silicon supported by a base semiconductor, and other semiconductor structures. The semiconductor need not be silicon-based. The semiconductor could as well be silicon-germanium, germanium or gallium arsenide.

A gate groove 27 is defined in the main surface 10 of the substrate 1. A gate dielectric 24 is disposed adjacent to the sidewalls of the gate groove 27. The gate dielectric 24 may be made of a suitable dielectric material having silicon oxide, silicon nitride, a hafnium compound such as hafnium oxide and others, a high-k material such as aluminum oxide (Al2O3) and others which are generally well known in the art. The gate dielectric 24 may as well include any layered structure including, for example, any of the materials listed above. The conductive material of the gate electrode 23 may be a conductive carbon filling 25. For example, the conductive carbon filling may completely fill the gate groove. By way of further example, the carbon filling may completely fill a lower or an arbitrary part of the gate groove.

By way of example, the term “conductive carbon” as used throughout this specification may include a material which is made of elemental carbon, i.e. carbon which is not contained in a chemical compound or a component of a chemical compound. The carbon layer may be, for example, a polycrystalline carbon layer. For example, the polycrystalline carbon layer may include regions in which the carbon is locally held in a SP2 modification, thus having a graphite-like structure. By way of example, carbon in a polycrystalline orientation may include a plurality of small crystalline regions, wherein no directional relationship is given between the single crystalline regions. Each of the single crystalline regions may be in a conductive carbon modification, for example, a graphite-like modification. By way of example, the conductive carbon may be doped with a suitable dopant such as an element selected from group III or group IV elements, including, for example, boron, phosphorus or arsenic. Accordingly, a resistivity of a correspondingly formed carbon layer may be further reduced. Furthermore, such a conductive carbon layer may be intercalated with metal halogenides, such as, for example, arsenic fluoride (ASF5) or antimony fluoride (SBF5). Moreover, the crystallinity of the carbon may be changed during production.

Differently stated, the gate electrode may include a material which consists of conductive carbon, for example, carbon which is not component of a compound but which is elemental carbon. Moreover, the gate electrode may consist of conductive carbon. Nevertheless, as is clearly to be understood, the conductive carbon may be doped with a suitable dopant as has been mentioned above and may include any kind of additives. As is to be understood, the addition of any of these elements does not substantially change the elemental state of the carbon material. Accordingly, the conductive carbon includes elemental carbon at an amount of at least 90%.

A resistivity of the conductive carbon layer may be smaller than the resistivity of polysilicon. Accordingly, the resistivity of the carbon electrode may be reduced by a certain factor relative to that of polysilicon. By way of example, the conductivity of conductive carbon may be the conductivity of doped polysilicon multiplied by a factor between 10 and 100. Furthermore, conductive carbon is a mid-gap material. Accordingly, if conductive carbon is employed as a gate material, the threshold voltage of the transistor may be adjusted by the gate material. For example, by selecting the dopant of the carbon material, the threshold voltage of the transistor may be selected. By way of example, the threshold voltage may be finely controlled with a local channel implant.

The surface of the conductive carbon filling 25 may be disposed beneath the main surface 10 of the semiconductor substrate 1. By way of example, the top surface of the conductive carbon layer 25 may be substantially at the same height as the bottom side of the doped portions 21, 22. An insulating material 26 may be disposed above the conductive carbon filling 25. Due to the conductive carbon filling, the resistance of the gate electrode is typically reduced in comparison with a gate electrode made of polysilicon. Furthermore, the patterning, for example, a recess etch of the conductive carbon filling may be performed in an easy way. In the transistors described throughout this specification, the channel is formed between the first and the second source/drain portions 21, 22. The gate electrode 23 is configured to control a conductivity of this channel.

FIG. 2 illustrates a transistor 20 according to another embodiment. The cross-sectional view of FIG. 2 is taken between I and I′, as can be seen from FIGS. 7A and 7B. The transistor 30 illustrated in FIG. 2 includes a first and a second source/drain portions 31, 32 which are disposed adjacent to a main surface 10 of a semiconductor substrate 1. A gate groove 38 is defined in the main surface 10 of the substrate 1. A gate dielectric 34 is disposed adjacent to a sidewall of the gate groove 38. A conductive carbon layer 35 may optionally be formed as a conformal layer above the gate dielectric layer 34. By way of example, the conductive carbon layer 35 may be in contact with the gate dielectric layer 34. A conductive filling 37 may be disposed over the conductive carbon layer 35 so as to be in contact with the conductive carbon layer 35. For example, the conductive filling 37 may be made of any suitable metal including tungsten or titanium or a metal compound, and others which are generally well known in the art. Optionally, a thin barrier layer which may be made of Ti, TiN, TaN, may be disposed between the conductive carbon layer and the conductive filling 37. By way of example, the conductive carbon layer 35 may have a thickness of approximately 5 to 10 nm. The conductive carbon layer 35 as well as the conductive filling 37 may be recessed so that a top surface of the filling 37 as well as of the conductive carbon layer 35 is disposed beneath the main surface 10 of the substrate 1. An insulating material 36 may be disposed above the conductive filling 37 as well as the conductive carbon layer 35 so as to insulate the gate electrode from the portion above. The gate electrode 33 having the conductive carbon layer 35 as well as the conductive filling 37 is configured to control a current flowing between the first and the second source/drain portions 31, 32.

Accordingly, the gate electrode 33 includes a material having a lower resistivity than carbon while making use of the positive effects of the carbon layer. To be more specific, the carbon layer may be deposited, etched and patterned in an easy way. For example, the gate dielectric and other layers may not be damaged during the patterning of the carbon layer. The transistors 20 and 30 illustrated in FIGS. 1 and 2 may be modified in an arbitrary manner.

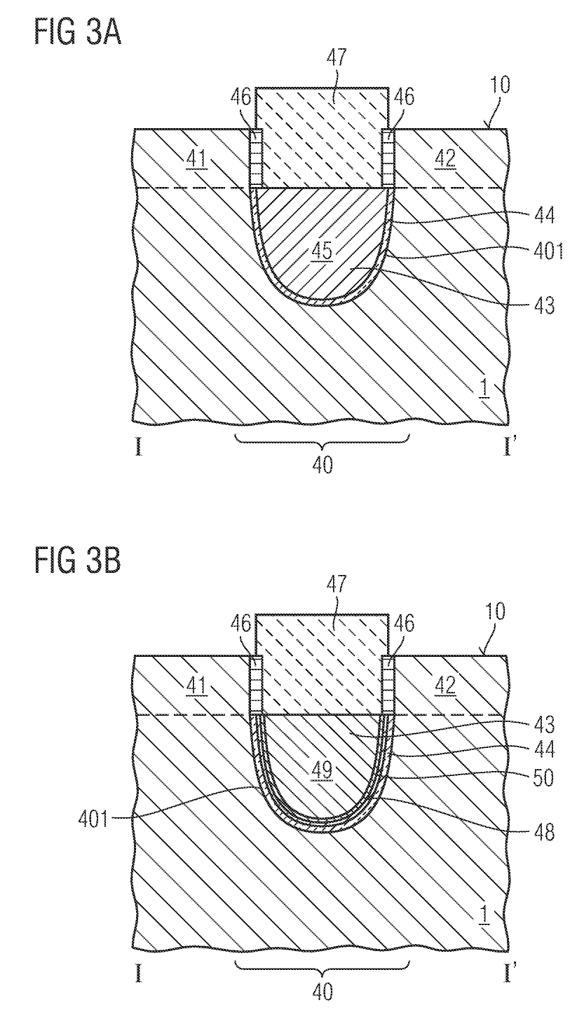

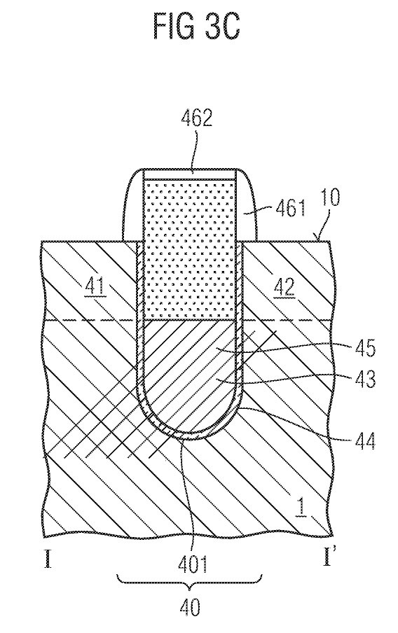

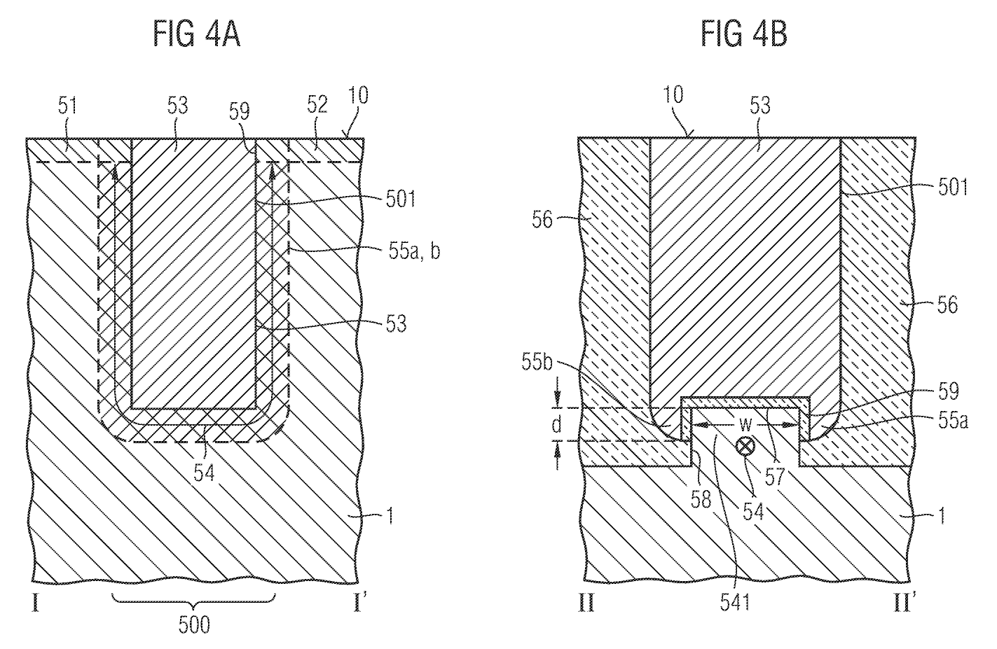

By way of example, as is illustrated in FIG. 3A, the transistor 40 may be formed in a similar manner as has been described above, having a first and a second source/drain portions 41, 42 and a gate electrode 43 which is disposed in a gate groove 401. The gate groove 401 may be filled with a conductive carbon filling 45 which is insulated from the semiconductor substrate 1 by a gate dielectric 44. An upper surface of the conductive carbon filling 45 is disposed beneath the main surface 10 of the semiconductor substrate 1. A conductive line segment 47 may be disposed above the conductive filling 45 so as to be in electrical contact with the conductive carbon filling 45. The conductive line segment 47 may include any suitable conductive material. For example, the conductive line segment 47 may include tungsten or titanium. The conductive line segment 47 may as well include conductive carbon which may be doped in the same or in a different manner compared with the conductive carbon material of the gate electrode. The conductive line segment 47 may be insulated from the first and second source/drain portions 41, 42 by an insulating spacer 46. The upper surface of the conductive line segment 47 may be disposed above or below the main surface 10 of the semiconductor substrate 1. In the context of the present specification, the term “main surface” refers to the planar surface of the semiconductor substrate, on which the various processing steps are to be performed.

In the modification illustrated in FIG. 3B, the gate electrode 43 includes a conductive carbon layer 48 as well as a conductive filling 49. The conductive carbon layer 48 optionally may be formed as a conformal layer and may have a thickness of approximately 5 to 10 nm. The conductive filling 49 may be made of any suitable metal or metal compound. Optionally, a conductive liner 50 may be disposed between the conductive carbon layer 48 and the conductive filling 49. The conductive liner 50 may, for example, include Ti, TiN or TaN. The conductive carbon layer 48 may be in contact with the gate dielectric 44. A conductive line segment 47 is disposed above the conductive filling 49 in the same manner as illustrated in FIG. 3A. The optional conductive liner 50 may be disposed between the conductive carbon layer 48 and the conductive filling 49 so as to increase the adhesion strength of the conductive filling to the carbon layer. The conductive liner 50 may have a thickness of approximately 1 nm.

FIG. 3C illustrates a further modification of the transistor. The transistor 40 may include a first and a second source/drain portions 41, 42 and a gate electrode 43 which is disposed in a gate groove 401. The gate groove 401 may be filled with a conductive carbon filling 45 which is insulated from the semiconductor substrate 1 by a gate dielectric 44. According to the embodiment illustrated in FIG. 3C, an upper surface of the conductive carbon filling 45 is disposed above the main surface 10 of the semiconductor substrate 1. An insulating capping layer 462 as well as insulating spacers 461 may be provided so as to isolate the carbon wordlines as well as the gate electrode from the outside. The cross-sectional views of FIGS. 3A, 3B and 3C are taken between I and I′ as can be seen from FIGS. 7A and 7B, for example.

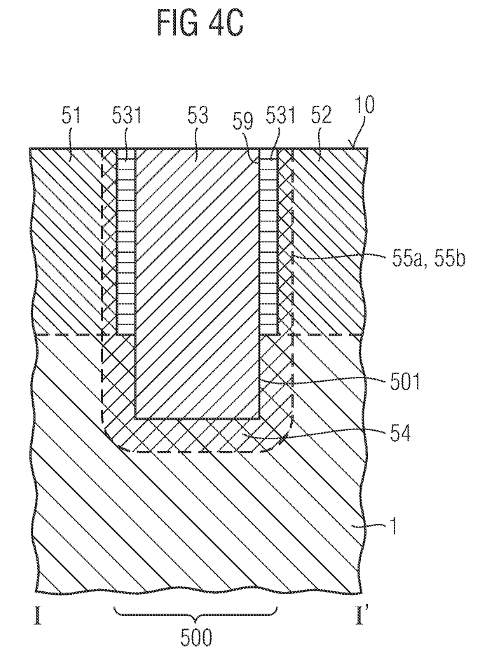

FIGS. 4A to 4B illustrate cross-sectional views of a transistor according to still another embodiment. The cross-sectional views in FIGS. 4A and 4B are taken between I and I′ and between II and II′, respectively, as can for example, be taken from FIGS. 7A and 7B. As is illustrated in FIG. 4A, a transistor 500 includes a first and a second source/drain portions 51, 52 which are disposed adjacent to a main surface 10 of the semiconductor substrate 1. A gate electrode 53 is disposed in a gate groove 501 which is defined in the main surface 10 of semiconductor substrate 1. The gate electrode 53 may include a conductive carbon filling as is, for example, illustrated in FIG. 1. Alternatively, the gate electrode 53 may as well include a carbon layer as well as a conductive filling, as is illustrated in FIG. 2. For example, the carbon layer may be a layer which may be conformal. The gate electrode 53 may further include vertical portions 55a, 55b which extend before and behind the drawing plane illustrated in FIG. 4A. FIG. 4B illustrates a cross-sectional view which is taken perpendicularly with respect to the cross-sectional view illustrated in FIG. 4A. As can be seen in FIG. 4B, isolation trenches 56 are formed adjacent to a substrate portion in which the transistor 500 is formed. The gate electrode laterally extends into the isolation trenches 56 so as to form the vertical portions 55a, 55b. The active area 541, in which the transistor is formed, has a width w. Moreover, the vertical portions 55a, 55b extend to a depth d which is measured from the top side 57 of the active area 541 to the bottom side of each of the vertical portions 55a, 55b. Accordingly, the channel 54 of the transistor 500 may have the shape of a fin or a ridge. The channel 54 may be enclosed at three sides thereof by the gate electrode 53.

Several modifications of the structure illustrated in FIGS. 4A and 4B may be made. For example, in the embodiment illustrated in FIG. 4B, the depth d is very small in comparison with the width of the active area. Accordingly, such a transistor is also referred to as a corner device. The transistor 500 may be as well be implemented as a FinFET in which the vertical portions 55a, 55b extend to a larger depth. Moreover, the width of the active area 541 may be further reduced, so that the channel may be fully depleted. Although in the drawings “U” shaped grooves are illustrated, it is clearly to be understood that the grooves may also be formed so as to have the shape of a “V” or a “W” or any other related shape. Moreover, any combination of these shapes may be implemented.

As is illustrated in FIG. 4C, the first and second doped portions 51, 52 may extend to a larger depth measured from the main surface 10. Moreover, a suitable insulating spacer 531 may be disposed between the gate electrode 53 and the first and second source/drain portions 51, 52. The transistor 500 illustrated in FIG. 4C also includes plate-like portions 55a, 55b. The cross-sectional view of FIG. 4C is taken between I and I′ as can be seen from FIGS. 7A and 7B.

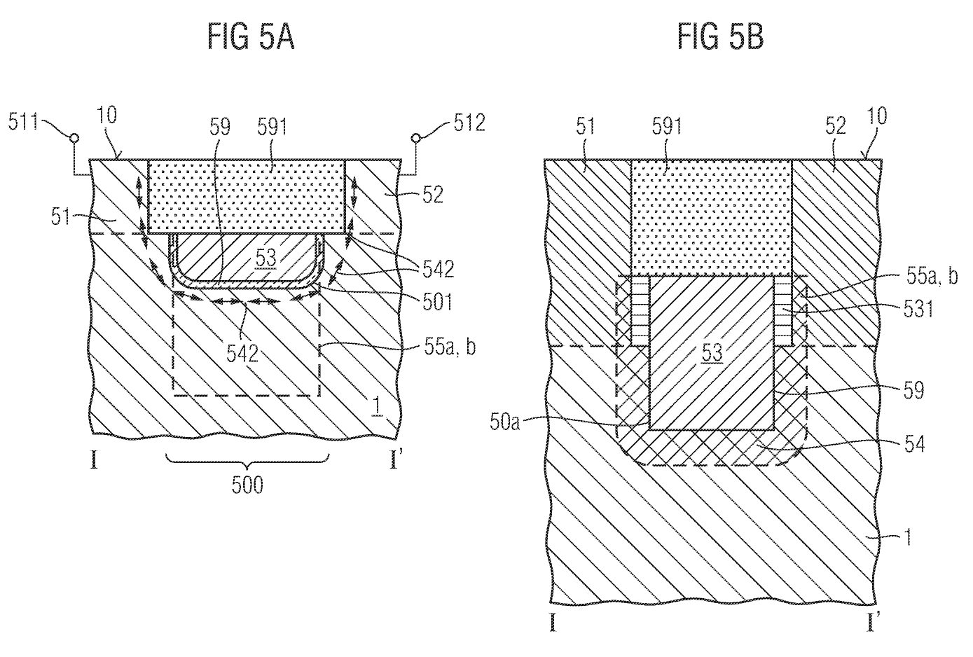

FIG. 5A illustrates a further embodiment of the invention. As can be seen, the transistor 500 illustrated in FIG. 5A includes a first and a second source/drain portions 51, 52 which are disposed adjacent to the main surface 10 of the semiconductor substrate 1. The gate electrode 53 is disposed in the gate groove 501. The gate electrode 53 is insulated from the substrate 1 by the gate dielectric 59. The gate electrode 53 may be made of a conductive carbon filling or may be made of a carbon layer, followed by the conductive filling, as is, for example, illustrated in FIG. 2. An insulating filling 591 may be disposed above the gate electrode 53. Moreover, the gate electrode 53 may include vertical portions 55a, 55b which extend in the planes before and behind the depicted drawing plane of FIG. 5A. The vertical portions 55a, 55b may extend to approximately twice the depth of the gate groove. The position of the vertical portions 55a, 55b is indicated by broken lines. Accordingly, a current path of an electrical current which flows between a first electrical contact 511 and a second electrical contact 512 includes a first vertical portion, followed by a horizontal portion, followed by a second vertical portion. The gate electrode 53 may form part of a corresponding wordline which may be completely disposed beneath the main surface 10 of the semiconductor substrate 1.

FIG. 5B illustrates a further embodiment of the invention. As can be seen, the bottom surface or bottom edge of each of the first and second source/drain portions 51, 52 extends to a deeper depth than the top surface of the conductive material of the gate electrode 53. By way of example, an insulating spacer 531 may be disposed between the gate electrode 53 and the source/drain portions 51, 52. An insulating material 591 may be disposed above the gate electrode 53. The cross-sectional views of FIGS. 5A and 5B are taken between I and I′ as can be seen from FIGS. 7A and 7B.

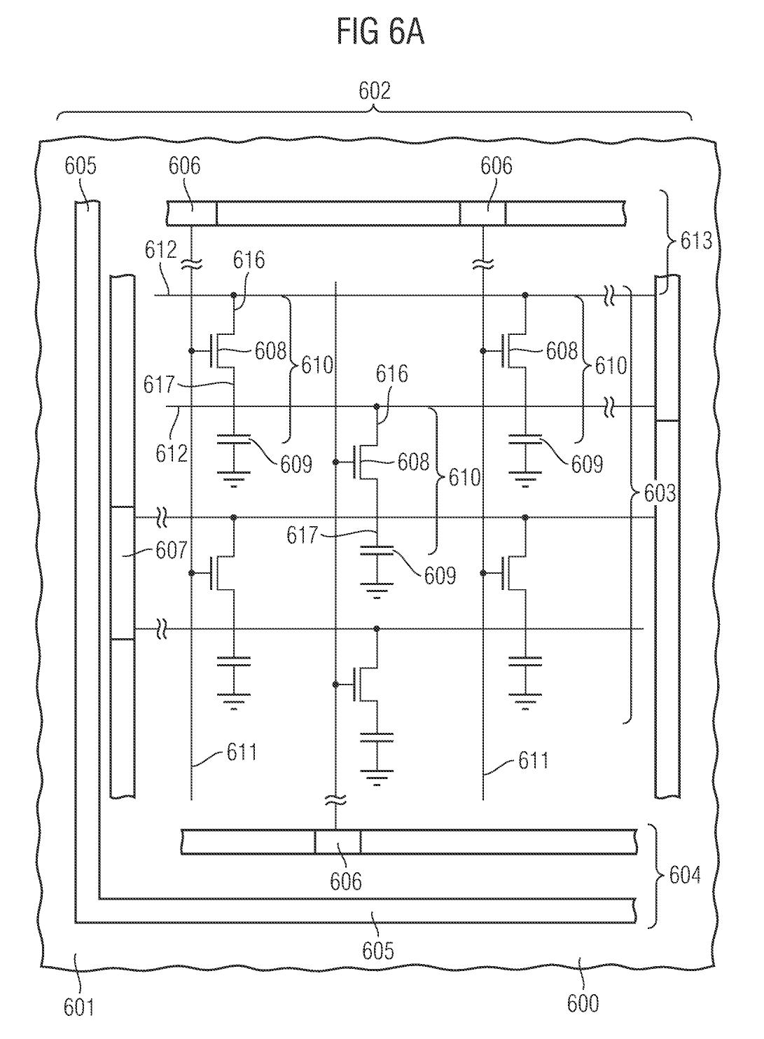

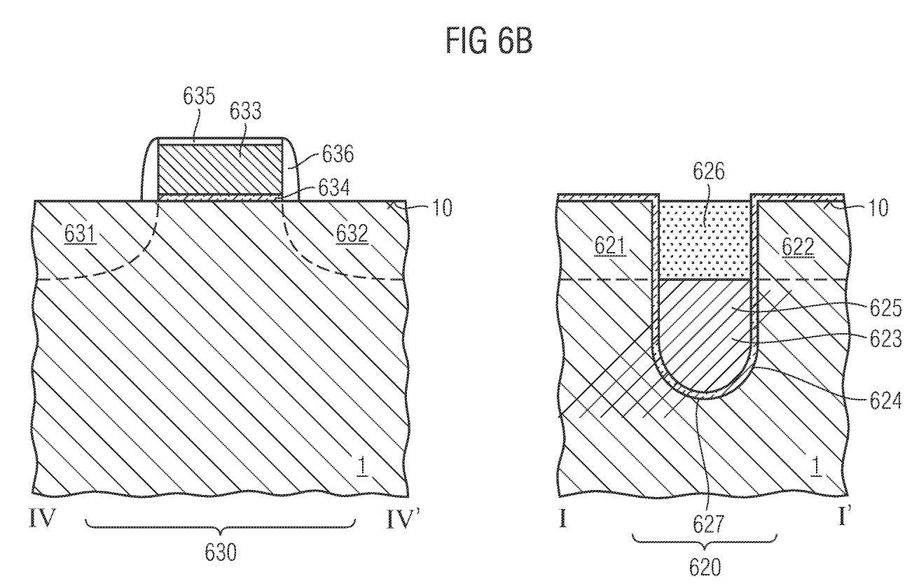

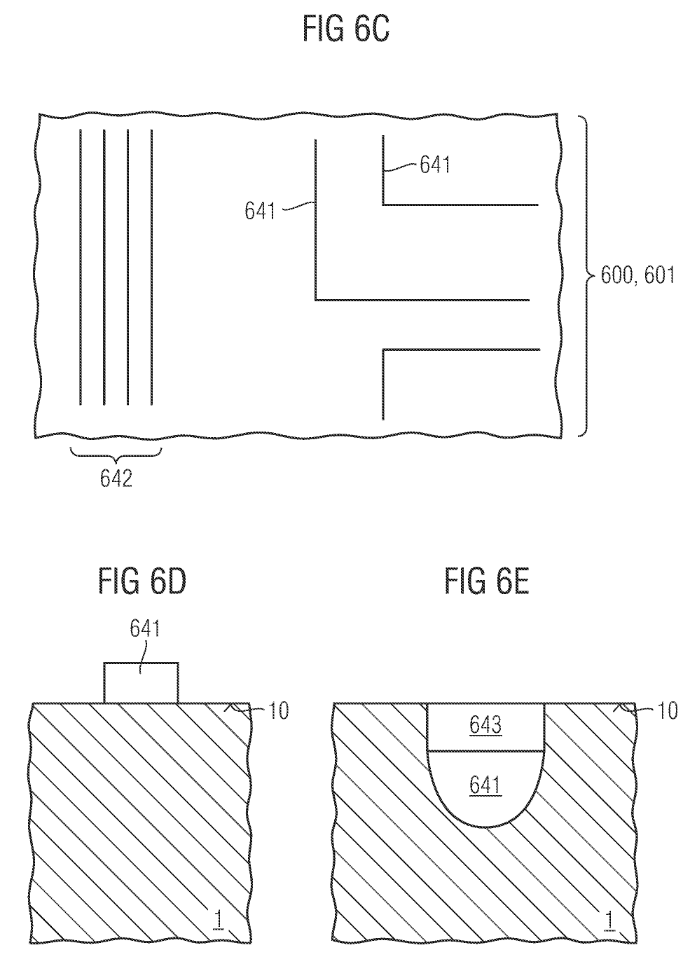

FIG. 6A illustrates a plan view of an exemplary integrated circuit 600 having a memory device 602 which may include transistors that are illustrated in FIGS. 1 to 5, respectively. The integrated circuit 600 may include a memory device 602 which is formed on a semiconductor chip 601. The memory device 602 may include a memory cell array portion 603 as well as a support portion 604. The memory cell array 603 may include memory cells 610 as well as corresponding conductive lines. By way of example, wordlines 611 may be disposed so as to extend along the first direction, and bitlines 612 may extend in a second direction which intersects the first direction. The memory cells 610 may include a storage element 609 such as a storage capacitor as well as an access transistor 608. By way of example, the access transistor 608 may be coupled to the storage element 609 via a node contact 617. Furthermore, the access transistor 608 may be coupled to a corresponding bitline 612 via a corresponding bitline contact 616. The wordlines 611 may be connected with the gate electrodes of the corresponding access transistor 608. The support portion 604 may include a core circuitry 613 as well as a peripheral portion 605. By way of example, the core circuitry 613 may include wordline drivers 606 as well as sense amplifiers 607. By way of example, a specific wordline 611 may be activated by addressing a corresponding wordline driver 606. Accordingly, the information of all the memory cells which are connected with the corresponding wordline 611, may be read out via bitlines 612. The signal transmitted by a bitline 612 is amplified in the sense amplifiers 607. By way of example, the wordlines 611 may be implemented as buried wordlines wherein the top surface of the wordlines 611 is disposed beneath the surface of the substrate. The layout and the architecture of the memory cell array may be arbitrary. By way of the example, the memory cells may be disposed in a 6 F² configuration or in any other suitable configuration of memory cells. Any of the transistors which may be disposed at an arbitrary position in the memory device may be implemented as a transistor which has been described above. For example, access transistors 608 and, optionally, wordlines 611 may correspond to the transistors explained above. For example, due to the reduced resistance of the material of the gate electrodes, the switching speed of a corresponding memory device may be remarkably removed. Consequently, such a memory device may be employed as a high performance DRAM device such as a graphics DRAM device.

FIG. 6B illustrates a cross-sectional view of an integrated circuit according to another embodiment of the invention. By way of example, a first transistor having a gate electrode as has been explained above and a second transistor having a planar gate electrode which includes a conductive carbon material may be combined in an integrated circuit. Accordingly, the first and the second transistors may be formed in one substrate. As is illustrated in FIG. 6B, the first transistor 620 includes a first and a second source/drain portions 621, 622. A gate groove 627 is defined in the surface 10 of the semiconductor substrate 1. A gate electrode 623 is formed in the gate groove 627. The gate electrode includes a conductive carbon material in the manner as has been explained above. By way of example, the conductive carbon material may be a carbon filling 625. Alternatively, the conductive carbon material may include a layer (not illustrated) which may be conformal and a further conductive filling. A gate dielectric 624 is formed so as to insulate the substrate 1 from the gate electrode 623. The integrated circuit further includes a second transistor 630 which includes a first and a second source/drain portions 631, 632. The second transistor 630 may be implemented as a planar transistor. Accordingly, the bottom side of the gate electrode 633 is disposed above the surface 10 of the semiconductor substrate. A gate dielectric 634 is disposed between the substrate 1 and the gate electrode 633. An insulating cap layer 635 and insulating spacers 636 may be provided on top and adjacent to the sidewalls of the gate electrode 633. The positions of the cross-sectional views between I and I′ and IV and IV′ may be taken from FIGS. 7A and 7B, respectively. The positions of the first and second transistors 620 and 630 may be arbitrarily selected. By way of example, if the integrated circuit is implemented as a memory device having a memory cell array portion as well as a support portion as has been explained above, the first transistor 620 may be disposed in the array portion and the second transistor 630 may be disposed in the support portion.

FIG. 6C illustrates a plan view of an integrated circuit 600 or a semiconductor chip 601. Conductive lines 641 are disposed on or in a semiconductor substrate 1. The conductive lines may be arranged in an array 642 of conductive lines or may be disposed at isolated positions. The conductive lines may include a conductive carbon material. For example, they may include a conductive carbon layer and a further conductive material. Alternatively, they may be made of conductive carbon as has been explained above. Due to the low resistance of the conductive carbon material, such an integrated circuit has an increased switching speed. Moreover, as has been explained above, the conductive lines may be patterned in a simple manner. FIGS. 6D and 6E illustrate cross-sectional views of an integrated circuit. For example, as is illustrated in FIG. 6D, the conductive lines may be disposed above the substrate surface 10 so that a bottom side of the conductive lines 641 is disposed on or above the substrate surface 10. Alternatively, the conductive lines 641 may be formed as buried lines. For example, they may be entirely or partially buried. For example, as is illustrated in FIG. 6E, an upper surface of the conductive lines may be disposed beneath the substrate surface 10. By way of further example, an upper surface of the conductive lines may be disposed above the substrate surface and a bottom surface of the conductive lines may be disposed beneath the substrate surface 10, in the manner as has been explained above. An insulating material 643 may be disposed on top of the conductive lines 641. The conductive lines 641 may have the same composition as the gate electrode which has been explained with reference to FIGS. 1, 2 and 3A to 3C. The conductive lines 641 may as well include a conductive layer which is disposed on top of the conductive carbon material. The integrated circuit may be implemented in various manners. For example, the integrated circuit may be a logic circuit, an application specific integrated circuit (ASIC), a processor, a microcontroller or others. The integrated circuit may as well be implemented as a memory device.

Generally, a memory device may include an array portion including memory cells and conductive lines. For example, the conductive lines may be wordlines for addressing a specific memory cell or bitlines for transmitting information. They further may include source lines for transmitting information. According to an embodiment, any of the conductive lines may include a conductive carbon material. Due to the reduced resistance of the conductive lines as has been explained above, the memory device has a reduced switching speed. For example, the wordlines may include a conductive carbon material. The memory device may be an arbitrary memory device having memory cells of an arbitrary type. For example, the memory cells may include transistors of the type as has been explained above. Accordingly, the gate electrodes may form part of a corresponding wordline. Optionally, the gate electrodes as well as the wordlines may be made of the same material. The memory cells may be DRAM memory cells as has been explained above, or memory cells of another type such as non-volatile memory cells having floating gate transistors, or NROM, SONOS, TANOS memory cells. Moreover, the memory cells may be memory cells having a transistor which may store an information, for example, any kind of floating body transistor. The memory may as well include memory cells of a MRAM (“magnetic random access memory”), PCRAM (“phase changing random access memory”), CBRAM (“conductive bridge random access memory”) or FeRAM (“ferroelectric random access memory”).

As is explained with reference to FIGS. 7A and 7B, any arbitrary arrangement of active areas, wordlines and bitlines may be implemented. For example, as is illustrated in FIG. 7A, the active areas 614 in which the transistors are formed may be disposed so as to extend parallel to the bitlines 612. Adjacent active areas 614 are insulated from each other by isolation trenches 615 which may be filled with an insulating material. The individual active area lines 614 may further be segmented so as to form active area segments. Nevertheless, active area segments may as well be isolated from each other by isolation field effect transistors, which may be driven in an off-state so as to isolate adjacent transistors from each other. Moreover, wordlines 611 may extend in a direction which is perpendicular with respect to the direction of the active areas 614. In addition, the bitlines 612 may be directly disposed above the active areas 614. FIG. 7A also indicates the direction of the cross-sectional views of the Figures illustrated.

FIG. 7B illustrates a further exemplary plan view of a memory device. As can be seen, active areas 614 are isolated from each other by isolation trenches 615 which are filled with an insulating material. The active areas 614 may extend in a direction which is slanted with respect to the direction of the bitlines 612. Accordingly, each of the active areas 614 intersects a plurality of different bitlines 612. The bitlines 612 extend perpendicularly with respect to the wordlines 611. At a point of intersection between an active area line 614 and a corresponding bitline, a bitline contact 616 may be formed. In the arrangement illustrated in FIG. 7B, each of the memory cells has an area of approximately 6 F², wherein F denotes the minimal structural feature size which may be obtained by the technology employed. By way of example, F may be less than 150 nm, for example, less than 110 nm and even less than 80 nm. By way of further example, F may be less than 70 nm or less than 50 nm.

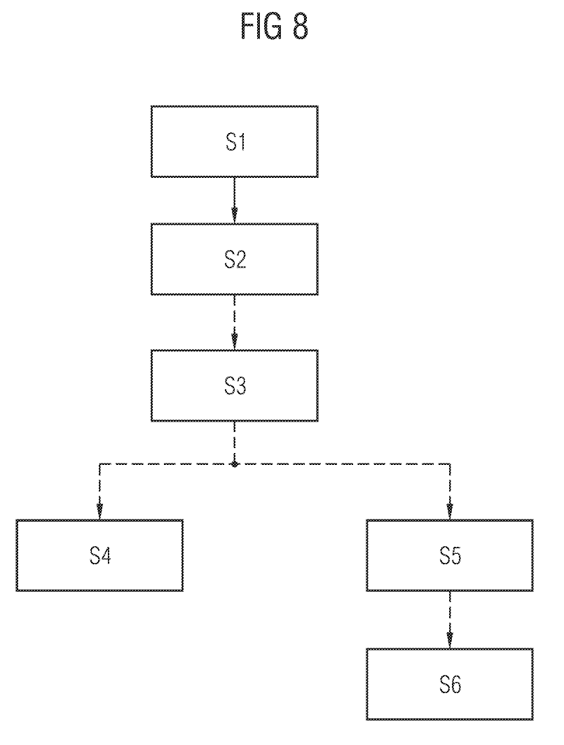

FIG. 8 schematically illustrates a flowchart illustrating an embodiment of the method of the present invention. First, a gate groove which extends in the semiconductor substrate surface is defined (S1). Thereafter, a conductive carbon layer is provided in the gate groove to form the gate electrode (S2). By way of example, the conductive carbon layer may be provided by a conformal deposition method, followed by providing a conductive filling to fill the gate groove. Alternatively, the conductive carbon layer may be provided by forming a conductive carbon filling. Optionally, the method may further include recessing the conductive carbon layer (S3). By way of example, an insulating material may be provided over the conductive carbon layer to fill the gate groove (S4). Alternatively, a conductive material may be provided over the conductive carbon layer. (S5) Thereafter, optionally, an insulating material may be provided over the conductive material (S6).

A method of forming an integrated circuit including a transistor may include defining a gate groove extending in a semiconductor substrate surface, providing a conductive carbon material in the gate groove to form a gate electrode, recessing the conductive carbon material and defining first and second source/drain portions adjacent to a main surface of the semiconductor substrate.

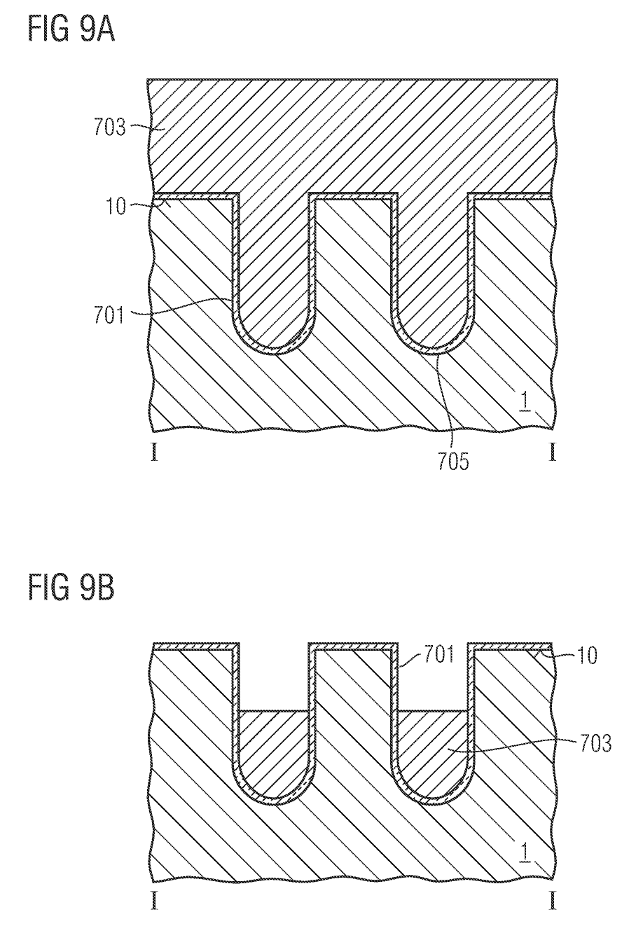

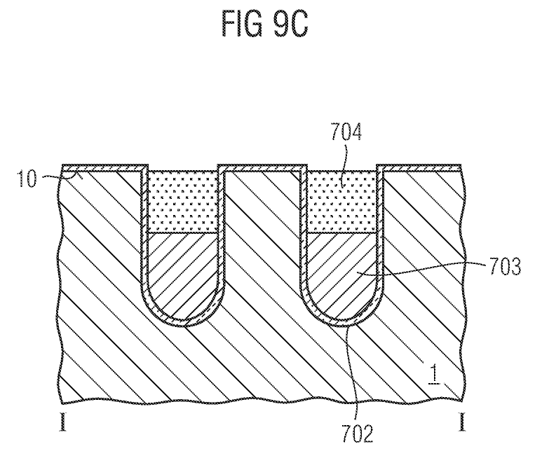

FIGS. 9A to 9C illustrate a method of forming an integrated circuit including a transistor according to an embodiment. First, in a main surface 10 of a semiconductor substrate 1, gate grooves 701 are defined. By way of example, the gate grooves 701 may be defined by etching. The positions of the gate grooves 701 may be photolithographically defined using an appropriate mask. For example, the gate grooves 701 may have a width of approximately IF and they may extend to a depth of more than 50 nm. For example, the depth of the gate grooves 701 may be more than 100 nm. By way of further example, the depth of the gate grooves may be less than 300 nm, for example, less than 250 nm. Thereafter, a suitable gate dielectric material 705 is provided in a manner as is generally well known. Thereafter, a conductive carbon filling 703 is provided.

By way of example, in the context of the present specification, a carbon layer such as the conductive carbon filling 703 may be formed by a method in which the carbon layer is deposited from a carbon-containing gas. Examples of the carbon-containing gas include methane, ethane, alcohol vapor and/or acetylene. According to an embodiment, a deposition temperature may be more than 900° C. and less than 970° C. A hydrogen partial pressure may be approximately 1 hPa and a carbon-containing gas may be fed so that a total pressure of more than 500 hPa and less than 700 hPa is set. By way of example, the temperature may be approximately 950° C. and the total pressure may be 600 hPa. Alternatively, the temperature may be more than 750° C. and less than 850° C. The hydrogen partial pressure may be approximately more than 1 hPa and less than 2 hPa, for example 1.5 hPa. By way of example, a partial pressure of the carbon-containing gas may be more than 8 hPa and less than 12 hPa. For example, the temperature may be approximately 800° C. and a partial pressure of the carbon-containing gas may be 10 hPa. By way of example, the conductive carbon layer may be formed of pyrolytic carbon, for example, carbon which is generated due to the thermal decomposition of a carbon-containing gas.

As is illustrated in FIG. 9A, the conductive carbon layer 703 may be deposited so as to completely fill each of the gate grooves 701. Thereafter, as is illustrated in FIG. 9B, a back-etching that may be performed so as to recess the upper surface of the carbon layer. By way of example, this may be accomplished by performing a plasma etching method using oxygen as an etching gas. The conductive carbon filling 703 may be recessed so that the top surface thereof is finally disposed at a predetermined height. During the formation of the conductive carbon layer, the gate dielectric material 705 will not be damaged or degraded. Accordingly, it is possible, to form a gate electrode without damaging the gate dielectric layer 705. Moreover, etching the conductive carbon layer may be performed in an easy manner, so that the gate dielectric layer 705 will not be damaged or degraded due to this etching step. Thereafter, for example, a suitable insulating material 704 may be filled in the gate grooves 701, followed by a suitable planarization step. An exemplary resulting structure is illustrated in FIG. 9C. As has been explained above, optionally, as well a conductive material may be filled in the upper portion of the gate grooves 701. Thereafter, the substrate may be further processed in a manner as is generally well known, for example, for defining the first and second source/drain portions. As is clearly to be understood, according to a modification of the above method, the conductive carbon material may not be recessed after the process illustrated with respect to FIG. 9A. In this case, the conductive carbon material may be patterned so as to form wordlines in a manner as is conventional, for example.

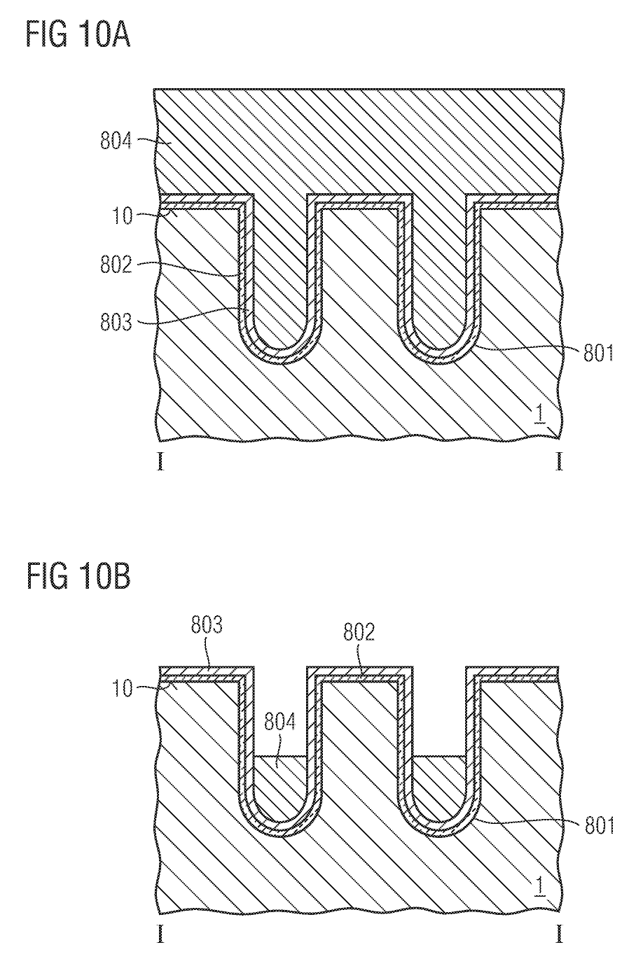

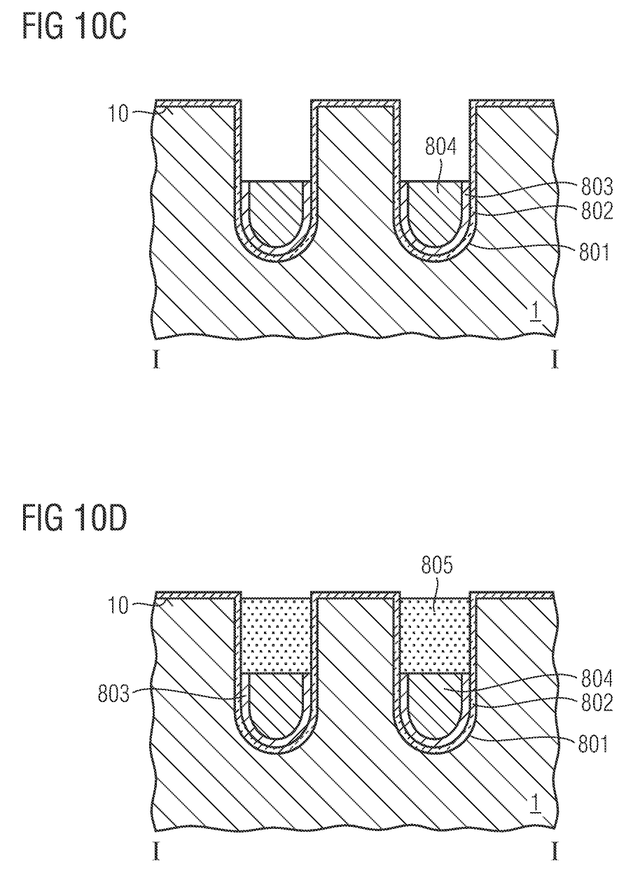

FIGS. 10A to 10D illustrate a method of forming an integrated circuit including a transistor according to another embodiment. After defining gate grooves 801 in a similar manner as has been explained above with reference to FIG. 9A, first, a suitable gate dielectric layer 802 is provided in a similar manner as has been explained above with reference to FIG. 9A. Thereafter, a conductive carbon layer 803 is deposited. By way of example, the carbon layer may have a thickness of approximately 5 to 10 nm. The conductive carbon layer 803 may be deposited in the same manner as has been explained above with reference to FIG. 9A. After depositing the carbon layer 803, a conductive filling 804 may be provided. Optionally, a conductive liner made of, for example, Ti, TiN, TaN may be deposited. The conductive liner (not illustrated) may have a thickness of less than 1 nm. Then, the conductive filling 804 is provided. For example, the conductive filling 804 may include any suitable metal or metal compound. Due to the conductive carbon layer 803 which is formed in an appropriate thickness, during the deposition of the conductive filling 804, the gate dielectric 802 will not be damaged or degraded. A cross-sectional view of the resulting structure is illustrated in FIG. 10A. Thereafter, the conductive filling 804 may be recessed by a suitable method. A cross-sectional view of an exemplary resulting structure is illustrated in FIG. 10B. Thereafter, taking the remaining portion of the conductive filling 804 as an etching mask, an etching process for etching the conductive carbon layer 803 is performed. Since the carbon layer 803 is made of conductive carbon, it may be removed by etching without attacking or damaging the gate dielectric 802. To be more specific, the carbon layer 803 may be removed by a simple plasma etching process. Thereafter, a further dielectric layer 805 may be filled in the upper portion of the gate grooves 801, followed by a planarization step. A cross-sectional view of an exemplary resulting structure is illustrated in FIG. 10D. As an alternative, as is clearly to be understood, after the process illustrated with respect to FIG. 10A, the conductive filling 804 may not be recessed. By way of example, after forming the conductive carbon layer 803 and the conductive filling 804, wordlines may be patterned as is usual.

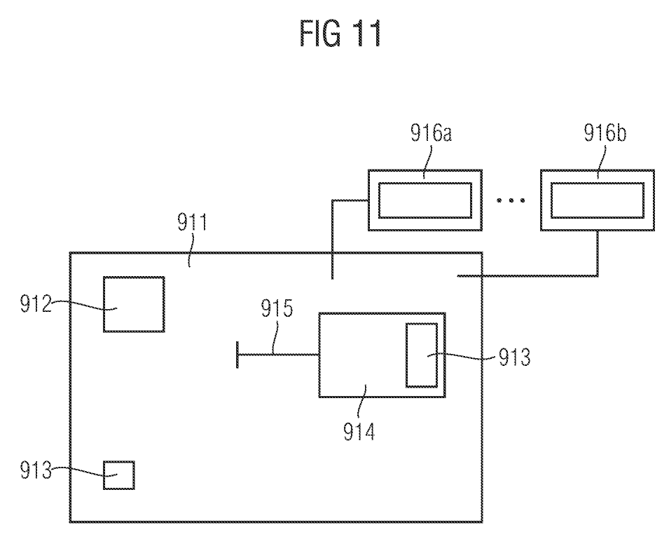

FIG. 11 schematically illustrates an electronic device 911 according to an embodiment. As is illustrated in FIG. 11, the electronic device 911 may include an interface 915 and a component 914 which is adapted to be interfaced by the interface 915. The electronic device 911, for example, or the component 914 may include an integrated circuit 600 or a transistor 20, 30, 40, 500 as has been explained above. The component 914 may be connected in an arbitrary manner with the interface 915. For example, the component 914 may be externally placed so as to be connected with the interface 915. Moreover, the component 914 may be housed inside the electronic device 911 and may be connected with the interface 915. By way of example, it is also possible that the component 914 is removably placed into a slot which is connected with the interface 915. When the component 914 is inserted into the slot, the integrated circuit 913 is interfaced by the interface 915. The electronic device 911 may further include an integrated circuit 913 as has been explained above. The electronic device 911 may further include a processing device 912 for processing data. In addition, the electronic device 911 may further include one or more display devices 916a, 916b for displaying data. The electronic device may further include components which are configured to implement a specific electronic system. Examples of the electronic system include a computer, for example, a personal computer, or a notebook, a server, a router, a game console, for example, a video game console, as a further example, a portable video game console, a graphics card, a personal digital assistant, a digital camera, a cell-phone, an audio system such as any kind of music player or a video system. For example, the electronic device 911 may be a portable electronic device.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor comprising:
a gate electrode, wherein the gate electrode is disposed in a gate groove formed in a semiconductor substrate, the gate electrode comprising a conductive carbon material.

2. The transistor of claim 1, comprising wherein the conductive carbon material is a layer over a gate dielectric layer, the gate electrode further comprising a conductive filling.

3. The transistor of claim 1, comprising wherein the conductive carbon material fills at least part of the gate groove.

4. The transistor of claim 1, comprising wherein an upper surface of the conductive carbon material is disposed below a main surface of the semiconductor substrate.

5. The transistor of claim 4, comprising wherein an insulating layer is disposed above the surface of the conductive carbon material.

6. The transistor of claim 4, comprising wherein a further conductive layer is disposed above the surface of the conductive carbon material.

7. The transistor of claim 1, comprising wherein the gate electrode further comprises vertical portions that are laterally adjacent to a channel.

8. The transistor of claim 1, comprising wherein the gate electrode is made of conductive carbon.

9. The transistor of claim 1, comprising wherein an upper surface of the conductive carbon material is disposed above a main surface of the semiconductor material

10. An integrated circuit comprising transistors, comprising:
a semiconductor substrate;
a gate electrode, wherein the gate electrode is disposed in a gate groove formed in the semiconductor substrate, the gate electrode comprising a conductive carbon material.

11. The integrated circuit of claim 10, further comprising conductive lines to connect predetermined gate electrodes with each other.

12. The integrated circuit of claim 11, comprising wherein an upper surface of the conductive lines is disposed beneath a main surface of the semiconductor substrate.

13. The integrated circuit of claim 10, comprising wherein the conductive carbon material is a conformal layer over a gate dielectric layer, the gate electrode further comprising a conductive filling.

14. The integrated circuit of claim 10, comprising wherein the conductive carbon material is a filling.

15. The integrated circuit of claim 10, comprising wherein an upper surface of the conductive carbon material is disposed below a main surface of the semiconductor substrate.

16. The integrated circuit of claim 10, comprising wherein an upper surface of the conductive carbon material is disposed above a main surface of the semiconductor substrate.

17. The integrated circuit of claim 11, comprising wherein the conductive lines are made of a metal or a metal compound.

18. The integrated circuit of claim 10, comprising wherein the gate electrodes form part of a conductive line connecting predetermined gate electrodes with each other.

19. The integrated circuit of claim 18, comprising wherein an upper surface of the conductive lines is disposed beneath a main surface of the semiconductor substrate.

20. The integrated circuit of claim 18, comprising wherein the conductive carbon material is a conformal layer over a gate dielectric layer, the gate electrode further comprising a conductive filling.

21. The integrated circuit of claim 18, comprising wherein the conductive carbon material is a conductive carbon filling.

22. The integrated circuit of claim 18, comprising wherein an upper surface of the conductive carbon material is disposed below a main surface of the semiconductor substrate.

23. The integrated circuit of claim 10, comprising wherein the gate electrode is made of conductive carbon.

24. The integrated circuit of claim 18, comprising wherein an upper surface of the conductive carbon material is disposed above a main surface of the semiconductor substrate.

25. The integrated circuit of claim 18, further comprising a planar transistor comprising a gate electrode, wherein a bottom side of the gate electrode is disposed above a main surface of the semiconductor substrate.

26. An integrated circuit comprising a transistor including:
a semiconductor substrate;
a gate electrode, a first and a second source/drain portions, wherein the gate electrode is disposed in a gate groove formed in the semiconductor substrate;
the gate electrode comprises a conductive carbon layer, an upper surface of the conductive carbon layer being disposed beneath a main surface of the semiconductor substrate; and
wherein the first and the second source/drain portions are disposed adjacent to the main surface of the semiconductor substrate.

27. The integrated circuit of claim 26, comprising wherein the conductive carbon layer is a layer over a gate dielectric layer, the gate electrode further comprising a conductive filling.

28. The integrated circuit of claim 26, comprising wherein the conductive carbon layer is a filling.

29. The integrated circuit of claim 26, comprising wherein an insulating layer is disposed above the surface of the conductive carbon layer.

30. The integrated circuit of claim 26, comprising wherein a further conductive layer is disposed above the surface of the conductive carbon layer.

31. The integrated circuit of claim 26, comprising wherein the gate electrode further comprises vertical portions that are laterally adjacent to a channel.

32. The integrated circuit of claim 26, comprising wherein the gate electrode is made of conductive carbon.

33. A method of forming an integrated circuit including a transistor comprising:
defining a gate groove extending in a semiconductor substrate;
providing a conductive carbon material in the gate groove to form a gate electrode.

34. The method of claim 33, comprising providing the conductive carbon material comprises depositing a conductive carbon layer over a gate dielectric layer, the method further comprising providing a further conductive material in the gate groove.

35. The method of claim 33, comprising providing the conductive carbon material comprises providing a conductive carbon filling.

36. The method of claim 33, comprising recessing the conductive carbon material so that an upper surface of the conductive carbon material is disposed beneath a main surface of the semiconductor substrate.

37. The method of claim 36, comprising providing an insulating material over the conductive carbon material.

38. The method of claim 36, comprising providing a conductive material over the conductive carbon material.

39. The method of claim 35, comprising defining the gate groove further comprises defining vertical portions of the gate electrode.

40. An integrated circuit comprising a substrate and conductive lines, wherein the conductive lines include a conductive carbon material.

41. The integrated circuit of claim 40, comprising wherein the conductive lines are formed in a semiconductor substrate having a main surface and an upper surface of the conductive lines is disposed beneath the main surface.

42. The integrated circuit of claim 40, comprising wherein the integrated circuit is a memory device comprising an array portion including memory cells and wordlines, wherein the wordlines comprise the conductive carbon material.

43. The integrated circuit of claim 42, comprising wherein the memory cells and the wordlines are formed in a semiconductor substrate having a main surface and an upper surface of the wordlines is disposed beneath the main surface.

44. The integrated circuit of claim 43, comprising wherein the wordlines are formed in wordline grooves and the conductive carbon material is a conductive carbon layer which is disposed neighbouring a bottom side of the groove, the wordlines further comprising a conductive filling.

45. The integrated circuit of claim 42, comprising wherein the wordlines are formed in wordline grooves and the conductive carbon material is a filling.

46. A memory device comprising:
an array portion including memory cells, the memory cells including transistors comprising a gate electrode, wherein the gate electrode is disposed in a gate groove formed in a semiconductor substrate, the gate electrode comprising a conductive carbon material.

47. The memory device of claim 46, comprising wherein the array portion further comprises wordlines and the gate electrodes form part of the wordlines.
